(19) United States
(12) Patent Application Publication
(10) Pub. No.: US 2017/0357075 A1
(43) Pub. Date: Dec. 14, 2017

(54) OPTICAL ELEMENT

(71) Applicant: SUMITOMO PRECISION PRODUCTS CO., LTD., Hyogo (JP)

(72) Inventor: Ryohei UCHINO, Hyogo (JP)

(73) Assignee: SUMITOMO PRECISION PRODUCTS CO., LTD., Hyogo (JP)

(21) Appl. No.: 15/524,919

(22) PCT Filed: Nov. 13, 2015
(86) PCT No.: PCT/JP2015/082020

§ 371 Date: May 5, 2017

(30) Foreign Application Priority Data
Nov. 20, 2014 (JP) 2014-235189

(51) Int. Cl. G02B 7/00; B81B 3/00; G03F 7/20; G02B 7/02; G02B 26/08

(52) U.S. Cl. CPC G02B 7/003; G02B 7/023; G02B 26/085; G03F 7/70266; B81B 3/0045; B81B 2201/033; B81B 2203/051; G02B 26/0858

(57) ABSTRACT

An optical filter device (1000) includes: a first mirror (101) transmitting portion of incident light; a second mirror (201) spaced apart from the first mirror (101), and transmitting portion of the incident light; actuators (300) driving the first mirror (101) to change a space between the first mirror (101) and the second mirror (201); and a detection electrode (400) detecting displacement of the first mirror (101). The detection electrode (400) includes: a movable comb electrode (410) including movable combs (414) and connected to the first mirror (101); and a stationary comb electrode (420) including stationary combs (424) facing the movable combs (414) in parallel with each other. The movable combs (414) are displaced in parallel with the stationary combs (424) when the movable comb electrode (410) is displaced together with the first mirror (101).

### TECHNICAL FIELD

A technique disclosed here relates to an optical element.

### BACKGROUND ART

A typically known optical element has an actuator drive a mirror. A known optical filter device receives incident light, and let portion of the incident light exit such that the exiting light has a specific wavelength.

For example, PATENT DOCUMENT 1 discloses an optical filter device including two mirrors spaced away from each other, and having an actuator adjust the space between the two mirrors to change the wavelength of exiting light. One of the mirrors is driven by electrostatic force generated between a pair of electrodes arranged in parallel. This optical filter device previously obtains the relationship of a wavelength of the exiting light to a drive voltage for generating the electrostatic force, and stores the relationship. Based on the relationship, the optical filter device selects a drive voltage corresponding to a desired wavelength. In addition, this optical filter device corrects the drive voltage based on a wavelength of actually exiting light to output light having a desired wavelength.

### CITATION LIST

### Patent Documents

PATENT DOCUMENT 1: Japanese Unexamined Patent Publication No. 2013-152489

### SUMMARY OF THE INVENTION

### Technical Problem

An optical element having an actuator drive a mirror is required to accurately detect displacement of the mirror. For accurately controlling the wavelength of the exiting light in the above optical filter device, a possible option is to detect the displacement of the two mirrors and precisely control the space between the mirrors, other than to correct the drive voltage based on the wavelength of the actually exiting light as described above. Furthermore, not only for optical filter devices but also for optical elements in general, precision is required in detecting displacement of a moving unit driven by an actuator.

A technique disclosed here is conceived in view of the above issues, and attempts to precisely detect displacement of a moving unit in an optical element.

### Solution to the Problem

An optical element disclosed here includes: a moving unit; an actuator driving the moving unit; and a detection electrode detecting displacement of the moving unit, the detection electrode including: a movable comb electrode including movable combs and connected to the moving unit; and a stationary comb electrode including stationary combs facing the movable combs in parallel with each other, and the movable combs being displaced in parallel with the stationary combs when the movable comb electrode is displaced together with the moving unit.

Such features make it possible to detect the displacement of the moving unit based on the change in the capacitance between movable comb electrode and the stationary comb electrode.

In detecting the change in capacitance between two electrodes, another possible option is to arrange two plate electrodes in parallel with each other, and detect the capacitance created due to the change in the space between the two plate electrodes. However, the capacitance between the plate electrodes is inversely proportional to the space, and the wider the space is, the less precise the detection of the capacitance is.

In contrast, the use of comb electrodes solves the problem of the plate electrodes. In the comb electrodes, the movable combs of the movable comb electrode and the stationary combs of the stationary comb electrode face each other without contact. In this state, the movable comb electrode is displaced such that the overlapping areas of the movable combs and the stationary combs change, followed by the change in the capacitance between the movable combs and the stationary combs. Since the capacitance of the comb electrodes is proportional to the overlapping areas, the change in capacitance may be precisely detected.

In addition, the movable combs are displaced in parallel with the stationary combs. Such a feature makes it possible to detect the change in the capacitance more precisely.

Specifically, the movable comb electrode tilts with respect to the stationary comb electrode when displacement of a member is detected based on the capacitance between the movable comb electrode and the stationary comb electrode. Here, an overlapping portion of a movable comb and a stationary comb is not always shaped into a rectangle. The overlapping area changes in shape such as a rectangle, a triangle, and a polygon having five angles or more, depending on a tilted state of the movable comb. Accordingly, the overlapping area does not always change in proportion to the displacement of the movable comb. As a result, the relationship of the displacement of the member corresponding to the change in the capacitance changes depending on a tilted state of the movable comb, making it difficult to control the displacement of the member. In addition, in the tilting of the movable comb electrode, the displacement with respect to the tilt angle becomes greater as the tilted portion is farther distant from a center of the tilt. If the displacement of the member becomes great, a portion, of the movable comb, distant from the center of the tilt does not face the stationary comb. Hence, the distance keeps the capacitance from changing. Specifically, the configuration in which the movable comb electrode tilts does not effectively utilize the overlapping area of the movable comb and the stationary comb for detecting the change of the capacitance.

Whereas, in the case of a configuration in which a movable comb is displaced in parallel with a stationary comb, an overlapping area of the movable comb and the stationary comb changes substantially in proportion to the displacement of the movable comb. Such a feature makes it possible to detect the displacement of the moving unit with uniform precision no matter how much the displacement is. Specifically, the precision in detecting the displacement of the moving unit may be substantially equal throughout an area in which the displacement of the moving unit is detectable. As a result, precision may improve in detecting the displacement of the moving unit throughout the displacement detectable area. Moreover, the relationship of a displacement of the moving unit to a change in the capacitance is uniform throughout the displacement detectable area. Such a feature allows the displacement of the moving unit to be more controllable. In addition, the displacement of movable combs is substantially the same as that of the moving unit. Such a feature makes it possible to effectively utilize the areas of the movable combs and the stationary combs to detect the change of the capacitance.

### Advantages of the Invention

The optical element may precisely detect the displacement of a moving unit.

### BRIEF DESCRIPTION OF THE DRAWINGS

FIG. 1 is a cross-sectional view of an optical filter device.

FIG. 2 is a plan view of a first unit.

FIG. 3 is an enlarged plan view of hinges and a detection electrode.

FIG. 4 is a perspective view of the detection electrode in an initial state.

FIG. 5 is a schematic view illustrating how movable combs and stationary combs face each other in the initial state.

FIG. 6 is a perspective view of the detection electrode when a first mirror is displaced.

FIG. 7 is a schematic view illustrating how the movable comb and the stationary comb face each other when the first mirror is displaced.

FIG. 8 is a plan view of a shutter device.

### DESCRIPTION OF EMBODIMENT

An embodiment as an example is described in detail below with reference to the drawings.

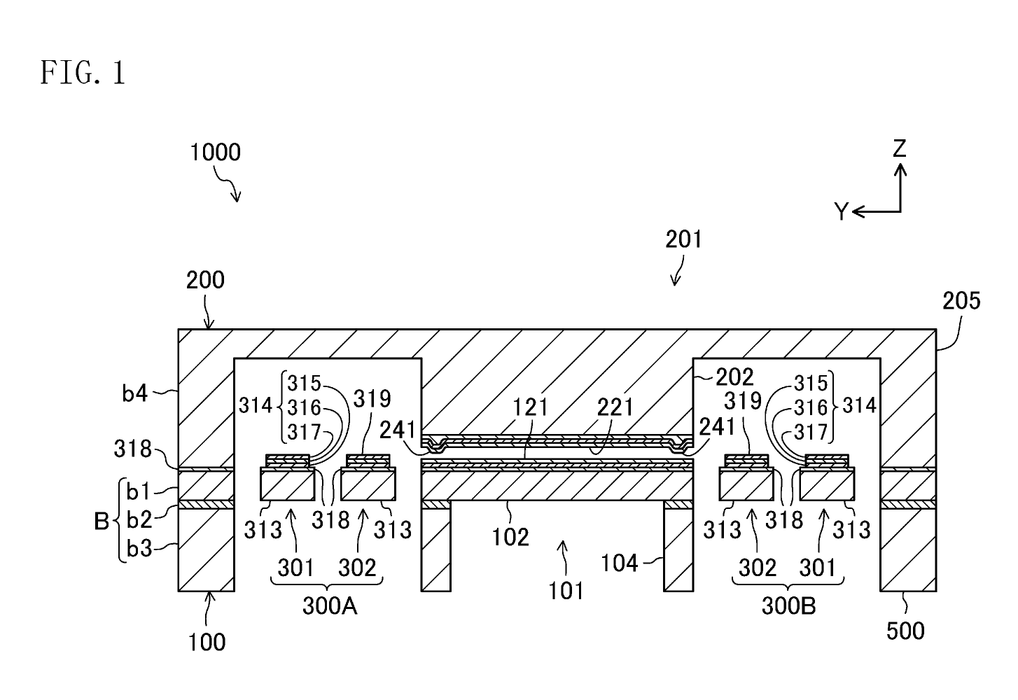

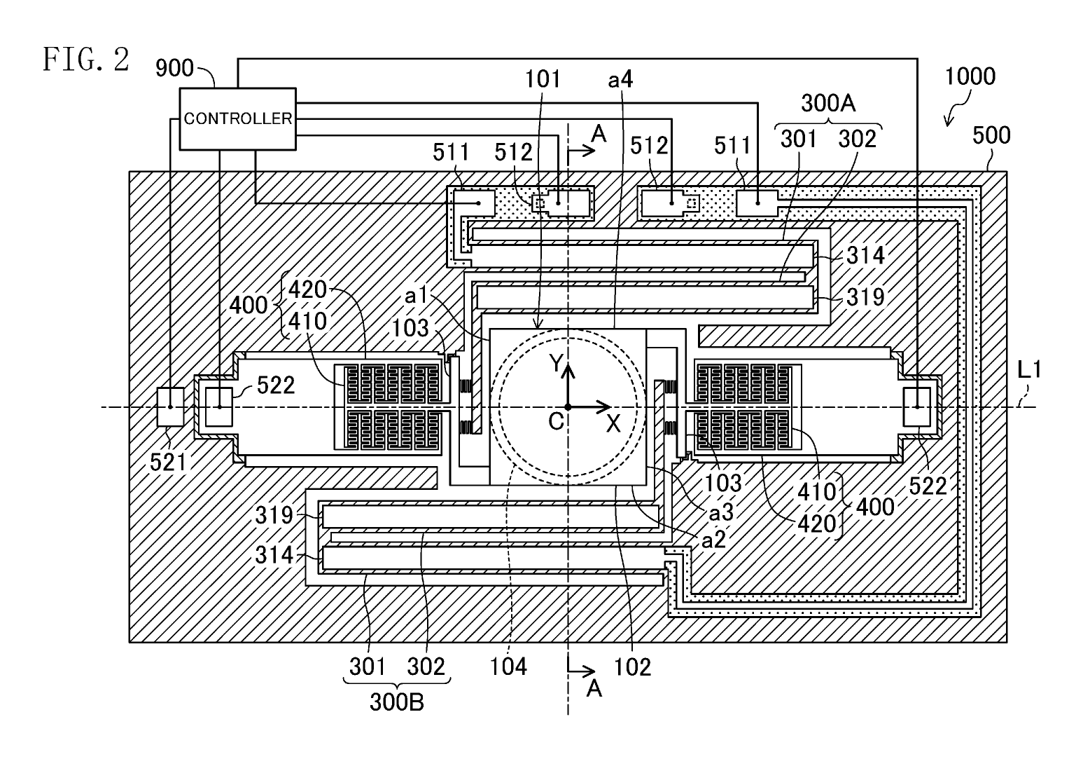

FIG. 1 is a cross-sectional view of an optical filter device 1000. FIG. 2 is a plan view of a first unit 100. Note that FIG. 1 is a cross-sectional view taken along line A-A in FIG. 2.

The optical filter device 1000 includes: the first unit 100 having a first mirror 101; a second unit 200 having a second mirror 201 facing the first mirror 101; and a controller 900. The first unit 100 and the second unit 200 lie on top of each other. Each of the first mirror 101 and the second mirror 201 lets portion of incident light transmit. Of the incident light into the second mirror 201, the optical filter device 1000 outputs from the first mirror 101 light having a wavelength corresponding to a space between the first mirror 101 and the second mirror 201. The optical filter device 1000 adjusts the space between the first mirror 101 and the second mirror 201 to adjust the wavelength of the exiting light. Specifically, the optical filter device 1000 is a variable wavelength filter device which employs the principle of a Fabry-Pérot resonator. The optical filter device 1000 is an example of an optical element.

The first unit 100 includes: the first mirror 101; two actuators 300 driving the first mirror 101 to change the space between the first mirror 101 and the second mirror 201; two detection electrodes 400 detecting displacement of the first mirror 101; and a frame 500.

The first unit 100 is made of a Silicon on Insulator (SOI) substrate B. The SOI substrate B includes a first silicon layer b1 formed of monocrystalline silicon, an oxide film layer b2 formed of SiO₂, and a second silicon layer b3 formed of monocrystalline silicon. These layers are stacked on top of one another in the stated order.

The frame 500 is shaped into a substantially rectangular frame in a planar view. The frame 500 includes the first silicon layer b1, the oxide film layer b2, and the second silicon layer b3. Note that the frame 500 has a surface to the first silicon layer b1. On the surface, an SiO₂ film 318 is deposited. This SiO₂ film 318 is the same film as the SiO₂ film 318 of an actuator 300 to be described later.

The first mirror 101 includes: a mirror body 102; two attachments 103; and a cylinder 104 provided to the mirror body 102. The mirror body 102 is shaped into a substantial rectangle in a planar view. The mirror body 102 is formed of the first silicon layer b1 and a dielectric multilayer film 121 stacked on a surface of the first silicon layer b1. The dielectric multilayer film 121 includes high refractive index layers and low refractive index layers alternately stacked one on top of another.

For the sake of explanation, the following axes are defined: an X-axis passing through a center C of the mirror body 102 and lying in parallel with a pair of sides, of the mirror body 102, facing each other; a Y-axis passing through the center C of the mirror body 102 and lying in parallel with another pair of sides, of the mirror body 102, facing each other; and a Z-axis passing through the center C of the mirror body 102 and running perpendicular to both the X-axis and the Y-axis. Moreover, in the Z-axis direction, an upside in FIG. 1 may be referred to as “the upside”, and a downside in FIG. 1 may be referred to as “the downside.”

Each of the two attachments 103 is provided to a corresponding one of a pair of sides, of the mirror body 102, facing each other. The pair of sides lies in parallel with the Y-axis. One of the attachments 103 extends in the X-axis direction from an end of a first side a1 (an end to a second side a2) which is in parallel with the Y-axis. The attachment 103 then bends and extends in parallel with the first side a1, leaving a space between the attachment 103 itself and the first side a1. The other one of the attachments 103 extends in the X-axis direction from an end of a third side a3 (an end to a fourth side a4) which faces the first side a1. The attachment 103 then bends and extends in parallel with a third side a3, leaving a space between the attachment 103 itself and the third side a3. The attachments 103 are formed of the first silicon layer b1.

The cylinder 104 is formed to cylindrically extend in the Z-axis direction, and is provided to a surface, of the mirror body 102, opposite the dielectric multilayer film 121. The cylinder 104 is formed of the oxide film layer b2 and the second silicon layer b3. Specifically the cylinder 104 is integrally formed with the mirror body 102. Such a feature improves the flatness of the mirror body 102.

In the frame 500, the two actuators 300 are arranged in the Y-axis direction with the first mirror 101 sandwiched therebetween. Each of the actuators 300 has a base end connected to the frame 500, and a tip end to be a free end; that is, the actuator 300 is of a cantilever configuration. To the tip end (the free end), the first mirror 101 is connected. Each of the actuators 300 includes two beams connected together as if a single beam were folded into two in a principle surface of the SOI substrate B. The two beams include a first beam 301 curved toward one direction with respect to the principle surface, and a second beam 302 having no curve or curved less than the first beam 301. The first beam 301 and the second beam 302 are arranged in parallel with each other. Note that, in FIG. 2, when the two actuators 300 are distinguished from each other, the actuator 300 above the first mirror 101 is referred to as a first actuator 300A and the actuator 300 below the first mirror 101 is referred to as a second actuator 300B.

Specifically, in the first actuator 300A, the first beam 301 has a base end secured to the frame 500. In FIG. 2, the first beam 301 extends from the frame 500 in the X-axis toward the observer's right. The first beam 301 has a tip end to which the second beam 302 is connected. The second beam 302 turns back from the first beam 301, and extends in the X-axis direction toward the observer's left. The second beam 302 has a tip end bent toward the first mirror 101 in the Y-axis direction and extending. The tip end then enters the space between the mirror body 102 and the attachment 103 of the first mirror 101, and extends in parallel with the attachment 103. To the tip end of the second beam 302, the first mirror 101 is connected.

Meanwhile, in the second actuator 300B, the base end of the first beam 301 is secured to the frame 500. The first beam 301 extends from the frame 500 in the X-axis direction toward the observer's left. The first beam 301 has a tip end to which the second beam 302 is connected. The second beam 302 turns back from the first beam 301, and extends in the X-axis direction toward the observer's right. The second beam 302 has a tip end bent toward the first mirror 101 in the Y-axis direction and extending. The tip end then enters the space between the mirror body 102 and the attachment 103, and extends in parallel with the attachment 103. To the tip end of the second beam 302, the first mirror 101 is connected.

Specifically, in the first actuator 300A and the second actuator 300B, the first beams 301 are connected to the frame 500, and the second beams 302 are connected to the first mirror 101. Note that the first actuator 300A and the second actuator 300B are opposite in direction in which the first beams 301 extend from the frame 500 and the second beams 302 extend from the first beams 301.

Described next is a configuration of each beam. The first actuator 300A and the second actuator 300B are similar in configuration of each beam. For example, the first beams 301 of the first actuator 300A and the first beams 301 of the second actuator 300B are similar in configuration.

Each first beam 301 includes a beam body 313 and a piezoelectric element 314 stacked on a surface of the beam body 313.

The beam body 313 is shaped into a bar whose cross-section is rectangular. The beam body 313 is formed of the first silicon layer b1.

The piezoelectric element 314 is provided to a surface of the beam body 313. The SiO₂ film 318 is stacked on the surface of the beam body 313, and the piezoelectric element 314 is stacked on the SiO₂ film 318. The piezoelectric element 314 includes a lower electrode 315, an upper electrode 317, and a piezoelectric body layer 316 sandwiched between the lower electrode 315 and the upper electrode 317. The lower electrode 315, the piezoelectric body layer 316, and the upper electrode 317 are stacked on top of another on the SiO₂ film 318 in the stated order. The piezoelectric element 314 and the SOI substrate B are formed of different materials. Specifically, the lower electrode 315 is formed of a Pt/Ti film or an Ir/Ti film. The piezoelectric body layer 316 is formed of lead zirconate titanate (PZT). The upper electrode 317 is formed of an Au/Ti film.

When a voltage is applied to the upper electrode 317 and the lower electrode 315 of the piezoelectric element 314, the surface, of the beam body 313, on which the piezoelectric element 314 is stacked expands and contracts. The beam body 313 then curves with the piezoelectric element 314 facing inward.

The second beam 302 includes the beam body 313 and a dummy film 319. The beam body 313 has a surface on which the SiO₂ film 318 is deposited, and the dummy film 319 is stacked on the SiO₂ film 318. The dummy film 319 includes the lower electrode 315, the piezoelectric body layer 316, and the upper electrode 317. Specifically, the dummy film 319 and the piezoelectric element 314 are similar in configuration. However, no voltage is applied to the dummy film 319 and the dummy film 319 does not act as a piezoelectric element. Specifically, the lower electrode 315, the piezoelectric body layer 316, and the upper electrode 317 of the dummy film 319 are respectively insulated from the lower electrode 315, the piezoelectric body layer 316, and the upper electrode 317 of the piezoelectric element 314. Even if a voltage is applied to the piezoelectric element 314, such a configuration keeps the voltage from being applied to the dummy film 319, and the dummy film 319 does not act as a piezoelectric element.

The dummy film 319 is provided to cancel a warp of beams in an initial stage and by temperature change. Specifically, the SiO₂ film 318, the lower electrode 315, the piezoelectric body layer 316, and the upper electrode 317 are deposited by such a technique as sputtering on the surface of the beam body 313 included in the first beam 301 and formed of the first silicon layer b1. After the film, the electrodes, and the layer are deposited, the first beam 301 can warp due to, for example, a temperature change during the deposition. For example, a surface, of the beam body 313, on which a thin film is deposited can contract, causing the first beam 301 to warp upward with the surface facing inward. However, for example, the first beam 301 is connected to the second beam 302 as if a single beam were folded into two. Hence, the dummy film 319 similar to the piezoelectric element 314 is also deposited on the beam body 313 of the second beam 302. Specifically, the first beam 301 and the second beam 302 warp, while being arranged substantially in parallel with each other. As a result, the tip end of the first beam 301 and the base end of the second beam 302 rise; however, the tip end of the second beam 302 comes back to the same position, along the thickness of the SOI substrate B, as that of the base end of the first beam 301. Hence, at the tip end of the second beam 302, such a feature cancels the displacement of the SOI substrate B along the thickness due to the warp in the initial stage. Moreover, the first beam 301 includes such materials as silicon, SiO₂, and Pt/Ti, each having a different coefficient of thermal expansion (CTE), stacked on top of another. Thus, a change in temperature causes the films to contract based on their respective CTEs. Hence, the first beam 301 can warp. However, the second beam 302 is similar in stack structure to the first beam 301, causing the second beam 302 to warp as the first beam 301 does. As a result, the warp of the first beam 301 is reduced by the second beam 302, similar to the warp in the initial stage.

Each of the second beams 302 is connected to a corresponding one of the attachments 103 of the first mirror 101 via two hinges 105.

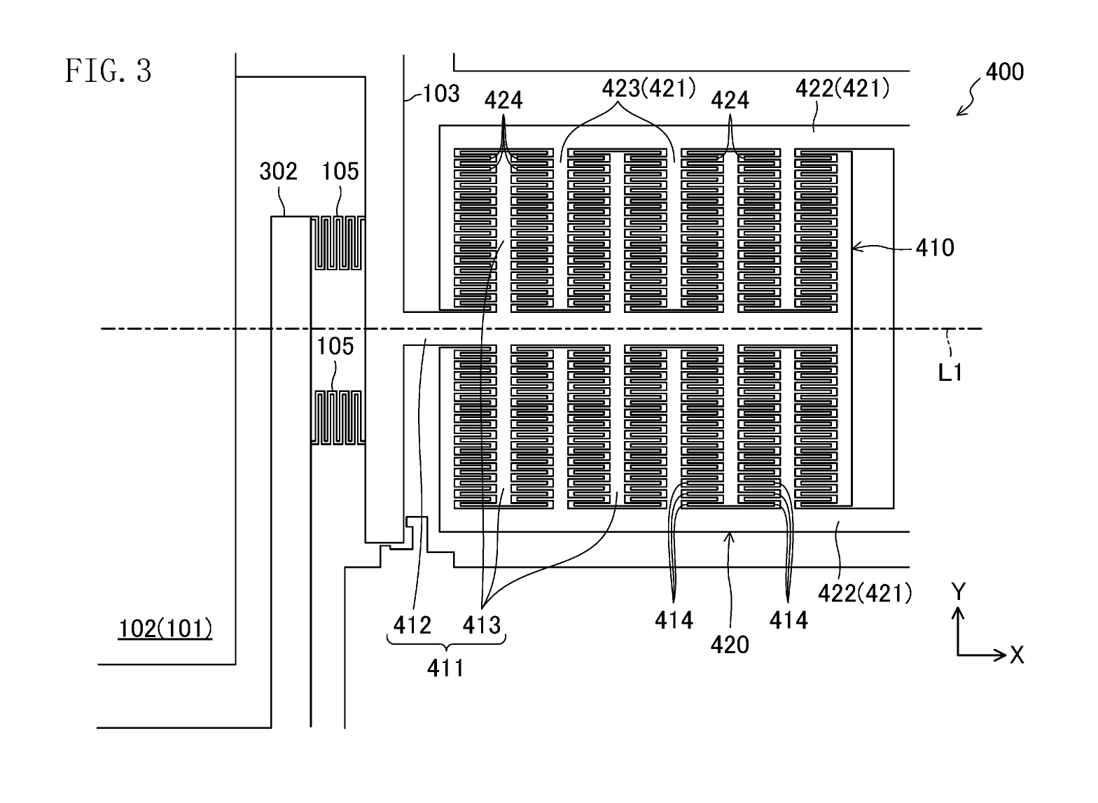

FIG. 3 is an enlarged plan view of the hinges 105 and a detection electrode 400. Formed of a meandering line, each of the hinges 105 is elastic. Specifically, the hinge 105 includes straight lines and a turn connecting ends of neighboring straight lines. As a whole, the hinge 105 has a meandering form. Since the straight lines extend along the Y-axis, the hinge 105 tends to curve about an axis along the Y-axis. The hinge 105 has an end connected to the tip end of the second beam 302, and another end connected to a portion, of the attachment 103, facing the mirror body 102. The hinge 105 is an example of a connector.

As illustrated in FIG. 2, the two hinges 105 are arranged to face each other across a straight line L1 passing through the center C of the mirror body 102 and extending in the X-axis direction. The two hinges 105 are equally spaced from the straight line L1 in the Y-axis direction.

The frame 500 is provided with drive terminals for applying a voltage to the first actuator 300A and the second actuator 300B. Specifically, the frame 500 has a surface provided with first feed terminals 511 and second feed terminals 512. One of the first feed terminals 511 is wired to the upper electrode 317 of the first beam 301 in the first actuator 300A. The other first feed terminal 511 is wired to the upper electrode 317 of the first beam 301 in the second actuator 300B. Furthermore, one of the second feed terminals 512 is electrically connected to the lower electrode 315 of the first beam 301 in the first actuator 300A. The other second feed terminal 512 is electrically connected to the lower electrode 315 of the first beam 301 in the second actuator 300B. On a SiO₂ film 128 of the frame 500, the lower electrode 315 and the piezoelectric body layer 316 are partially stacked. On the piezoelectric body layer 316, the first feed terminals 511 and their wiring, and the second feed terminals 512 are provided. Note that in a portion, of the piezoelectric element 314, to which a second feed terminal 512 is provided, an opening (illustrated by a broken line in FIG. 2) is formed to reach a lower electrode 315. Each of the second feed terminals 512 is provided to cover this opening, and electrically connected to a corresponding one of the lower electrodes 315. Applying a voltage to a pair of a first feed terminal 511 and a second feed terminal 512 allows the voltage to be applied to the piezoelectric element 314 of the first actuator 300A. Applying a voltage to another pair of a first feed terminal 511 and a second feed terminal 512 allows the voltage to be applied to the piezoelectric element 314 of the second actuator 300B.

The detection electrode 400 includes a movable comb electrode 410 connected to the first mirror 101, and a stationary comb electrode 420 provided to the frame 500.

The movable comb electrode 410 includes a base 411 connected to the first mirror 101, and movable combs 414 extending from the base 411. The base 411 is connected to the attachment 103 and cantilevered. The base 411 includes a first base portion 412, and second base portions 413. The first base portion 412 extends on the straight line L1 passing through the center C of the first mirror 101 and running along the X-axis. The second base portions 413 branch off, from portions of the first base portion 412, in opposed directions relative to the Y-axis direction. The movable combs 414 branch off, and extend, from each of the second base portions 413, in opposed directions relative to the X-axis direction. The movable combs 414 extend in parallel with one another. The movable comb electrode 410 is formed of the first silicon layer b1.

The stationary comb electrode 420 includes a base 421 connected to the frame 500, and stationary combs 424 extending from the bases 421. The base 421 is cantilevered and extends from the frame 500. The base 421 includes two first base portions 422, and multiple second base portions 423. The two first base portions 422 extend in parallel with each other along the X-axis, so that the first base portion 412 of the movable comb 414 is sandwiched between the two first base portions 422. The second base portions 423 branch off, from portions of each first base portion 422, in the Y-axis direction toward the first base portion 412. The second base portions 413 of the movable comb electrode 410 and the second base portions 423 are alternately arranged along the X-axis. The stationary combs 424 branch off, and extend, from each of the second base portions 423, in opposed directions relative to the X-axis direction. The stationary comb electrode 420 is formed of the first silicon layer b1. Note that the stationary comb electrode 420 is insulated from the movable comb electrode 410. Specifically, in the first silicon layer b1, the portion in which the stationary comb electrode 420 is formed is physically separated from its surrounding.

Hence, the movable combs 414 and the stationary combs 424 are interleaved each other. Specifically, the movable combs 414 and the stationary combs 424 are alternately arranged along the Y-axis. The movable combs 414 and the stationary combs 424 extend in parallel with each other in the X-axis direction, and face each other at spaced intervals along the Y-axis.

The surface of the first silicon layer b1 in the frame 500 is provided with detection terminals for detecting capacitance between the movable comb electrode 410 and the stationary comb electrode 420. Specifically, in the first silicon layer b1, a first detection terminal 521 is provided to a portion which is electrically conductive with the portion in which the movable comb electrode 410 is formed. Only one first detection terminal 521 is provided and shared with two movable comb electrodes 410. Moreover, in the first silicon layer b1, second detection terminals 522 are provided to a portion which is electrically conductive with the portion in which the stationary comb electrode 420 is formed. Two second detection terminals 522 are provided so that each of the two terminals corresponds to one of two stationary comb electrodes 420.

When the first mirror 101 is displaced, the movable comb electrode 410 is also displaced, followed by the displacement of the first mirror 101. The details thereof will be described later. As a result, the capacitance between the movable comb electrode 410 and the stationary comb electrode 420 changes. This change in capacitance is detected via the first detection terminal 521 and the second detection terminals 522.

Described next is a configuration of the second unit 200.

The second unit 200 includes the second mirror 201, and a frame 205 supporting the second mirror 201. The second unit 200 is formed of a silicon substrate b4.

The frame 205 is shaped into a substantially rectangular frame in a planar view. In a planar view, the frame 205 is similar in shape to the frame 500 of the first unit 100.

The second mirror 201 includes a mirror body 202 shaped into a substantial rectangle in a planar view. The mirror body 202 is formed of a silicon layer b4 and a dielectric multilayer film 221 stacked on a surface of the silicon layer b4. The mirror body 202 is not provided with the cylinder 104 provided to the first mirror 101; however, the silicon layer b4 of the mirror body 202 is thicker than the first silicon layer b1 of the mirror body 102. Such a feature ensures the flatness of the mirror body 202. The dielectric multilayer film 221 is provided to a surface, of the silicon layer b4 of the mirror body 202, facing the first mirror 101. The dielectric multilayer film 221 includes high refractive index layers and low refractive index layers alternately stacked one on top of another.

Moreover, protrusions 241 are provided to a surface, of the of the mirror body 202, facing the first mirror 101. The protrusions 241 are arranged at spaced intervals on a circumference of the first mirror 101 in the circumferential direction. These protrusions 241 face the first mirror 101 when the first unit 100 and the second unit 200 are laid on top of each other. Providing the protrusions 241 reduces a contact area between the first mirror 101 and the second mirror 201, successfully keeping both of the mirrors from sticking together.

The second mirror 201 is connected to the frame 205 with the silicon layer b4 extending into a flat-plate shape.

The first unit 100 and the second unit 200 in the above configuration are laid on top of each other, and the frame 500 and the frame 205 are bonded together via an adhesive. Here, the first unit 100 and the second unit 200 are laid on top of each other, with the dielectric multilayer film 221 of the second mirror 201 and the dielectric multilayer film 121 of the first mirror 101 facing each other. Such a feature allows the first mirror 101 and the second mirror 201 to be arranged in substantially parallel with each other at a spaced interval. Note that the frame 500 and the frame 205 may be bonded not with an adhesive but with another technique such as anodic boding.

The controller 900 includes a power source other than a processor and a memory, and controls the optical filter device 1000. The controller 900 supplies the actuators 300 with the drive voltage to cause the actuators 300 to adjust the space between the first mirror 101 and the second mirror 201.

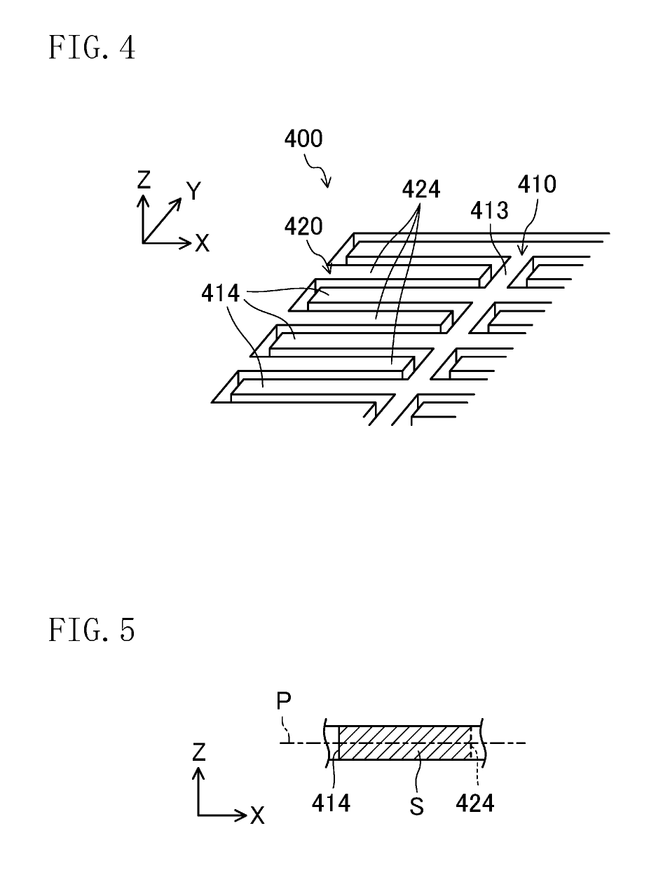

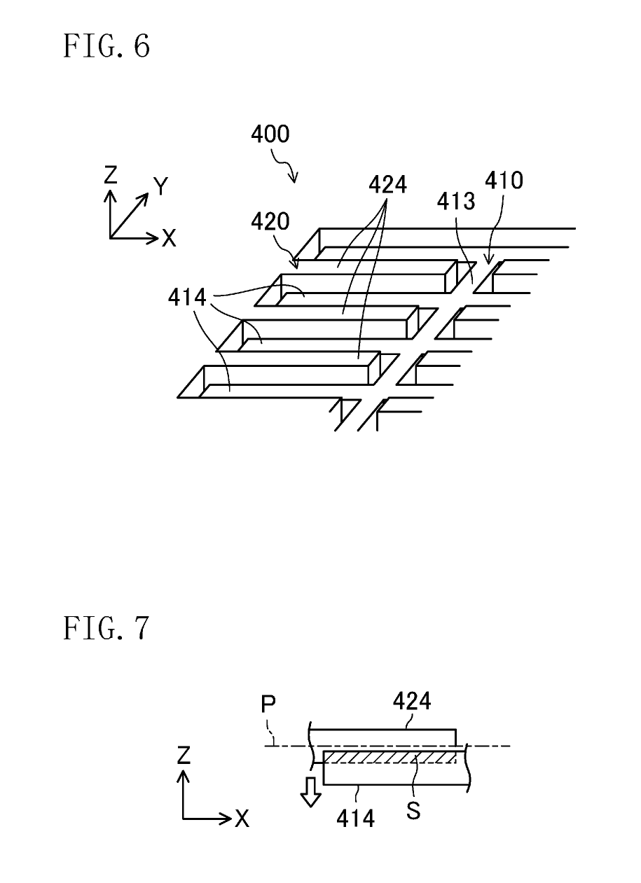

Described next is how the optical filter device 1000 operates. FIG. 4 is a perspective view of the detection electrode 400 in an initial state. FIG. 5 is a schematic view illustrating how the movable combs 414 and the stationary combs 424 face each other in the initial state. FIG. 6 is a perspective view of the detection electrode 400 when the first mirror 101 is displaced. FIG. 7 is a schematic view illustrating how the movable combs 414 and the stationary combs 424 face each other when the first mirror 101 is displaced.

In the optical filter device 1000, light enters the second mirror 201. The light passing through the second mirror 201 enters between the second mirror 201 and the first mirror 101. The light entering between the first mirror 101 and the second mirror 201 is reflected off the mirrors multiple times, and light having a wavelength corresponding to a space between the first mirror 101 and the second mirror 201 is output from the first mirror 101.

Here, the first mirror 101 is displaced and the space between the first mirror 101 and the second mirror 201 is adjusted. Such adjustment allows for a change in the wavelength of the light exiting from the first mirror 101.

Specifically, the controller 900 applies a drive voltage to the first feed terminals 511 and the second feed terminals 512. This drive voltage is applied to the piezoelectric element 314 of the first actuator 300A and the piezoelectric element 314 of the second actuator 300B, such that the first beams 301 of the first actuator 300A and the second actuator 300B curve. Each of the first beam 301 warps upward with respect to the surface of the SOI substrate B (warps toward the piezoelectric element 314), with the piezoelectric element 314 facing inward. Meanwhile, the second beam 302 does not practically curve, and is left substantially straight. Specifically, the first beam 301 extend from the frame 500 to warp upward, and, at the tip end of the first beam 301, the second beam 302 turns to extend substantially straight. Since the tip end of the first beam 301 slopes obliquely upward, the second beam 302 turning at the tip end of the first beam 301 also has the same slope as the tip end of the first beam 301 has. Specifically, the second beam 302 extends obliquely downward and subsequently straight. The tip end of the second beam 302 is positioned below the base end of the first beam 301; that is, below the surface of the SOI substrate B. As a result, the attachment 103 included in the first mirror 101 and to which the second beam 302 is connected also moves downward, opening the space between the first mirror 101 and the second mirror 201. Note that, compared with the state before the application of the drive voltage, the tip end of the second beam 302 is slightly displaced inward along the X-axis (i.e., toward the center C of the first mirror 101.) This displacement is absorbed by the hinge 105 extending along the X-axis.

Here, the controller 900 adjusts the drive voltage based on the result of detection by the detection electrode 400 to displace the first mirror 101 while keeping the first mirror 101 in substantially parallel with the second mirror 201.

Specifically, the wavelength of the light exiting from the optical filter device 1000 (hereinafter referred to as an “output wavelength”) depends on the space between the first mirror 101 and the second mirror 201. The space between the first mirror 101 and the second mirror 201 is determined based on a displacement of the first mirror 101. The first mirror 101 has the movable comb electrode 410 integrally formed therewith. Hence, when the first mirror 101 is displaced, the movable comb electrode 410 is also displaced together with the first mirror 101. The displacement in the movable comb electrode 410 changes overlapping areas S of the movable combs 414 and the stationary combs 424 corresponding to the respective movable combs 414 (hereinafter referred to as an “overlapping area”), changing the capacitance between the movable comb electrode 410 and the stationary comb electrode 420. Specifically, the wavelength of the light exiting from the optical filter device may be changed through the adjustment of the space between the first mirror 101 and the second mirror 201. The space between the first mirror 101 and the second mirror 201 may be detected based on the capacitance between the movable comb electrode 410 and the stationary comb electrode 420.

Thus, the controller 900 previously stores in the memory (i) a drive voltage corresponding to an output wavelength and provided to the actuators 300, and (ii) a capacitance of the detection electrode 400. When the output wavelength is set, the controller 900 reads from the memory a drive voltage corresponding to the output wavelength, and applies the drive voltage to each of the first actuator 300A and the second actuator 300B. Then, based on the capacitance to be detected via the detection electrode 400, the controller 900 performs feedback control on the drive voltage.

Specifically, one of the two movable comb electrodes 410 is provided to the attachment 103 included in the first mirror 101, and to which the first actuator 300A is attached. The other movable comb electrode 410 is provided to the attachment 103 included in the first mirror 101, and to which the second actuator 300B is attached. In other words, the one movable comb electrode 410 is displaced in response to the displacement of the first mirror 101 mainly by the first actuator 300A. The other movable comb electrode 410 is displaced in response to the displacement of the first mirror 101 mainly by the second actuator 300B. Hence, the controller 900 controls (i) a drive voltage applied to the first actuator 300A based on the capacitance of one of the detection electrodes 400, and (ii) a drive voltage applied to the second actuator 300B based on the capacitance of the other detection electrode 400. Specifically, the controller 900 adjusts the respective drive voltages for the first actuator 300A and the second actuator 300B so that the capacitance for each detection electrode 400 corresponds to a desired output wavelength. As a result, the first mirror 101 is in substantially parallel with the second mirror 201, and the space between the first mirror 101 and the second mirror 201 is set to correspond to a desired output wavelength.

In this configuration, the movable combs 414 are displaced in parallel with the stationary combs 424. Such a feature makes it possible to precisely detect the capacitance throughout a range of motion of the first mirror 101.

Specifically, the movable comb electrode 410 and the stationary comb electrode 420 are formed of the same first silicon layer b1. In the initial state; that is, when the first mirror 101 is not displaced, the movable comb electrode 410 and the stationary comb electrode 420 are positioned on the same plane as illustrated in FIGS. 4 and 5. This plane is imaginary, and hereinafter referred to as “reference plane P.” The reference plane P is in parallel with the surface of the first silicon layer b1. Here, as illustrated in FIG. 5, an overlapping area S of each movable comb 414 and the corresponding stationary comb 424 is basically the largest. In other words, the capacitance is the highest.

Moreover, the mirror body 102 of the first mirror 101 is also formed of the first silicon layer b1. In the initial state, the first mirror 101 is also positioned on the reference plane P as the movable comb electrode 410 and the stationary comb electrode 420 are.

From this state, the first mirror 101 shifts substantially in parallel in the Z-axis direction as described before; that is, the first mirror 101 moves approximately in parallel with a reference plane P. Here, the movable comb electrode 410 is integrally connected to the first mirror 101. Hence, as illustrated in FIGS. 6 and 7, the movable comb electrode 410 also moves approximately in parallel with the reference plane P. Specifically the movable comb 414 moves, staying in parallel with the stationary comb 424. As a result, the overlapping area S of the movable comb 414 and the stationary comb 424 decreases as illustrated in FIG. 7.

Here, the overlapping area S reduces in proportion to a displacement of the first mirror 101. The overlapping area of the movable comb 414 and the stationary comb 424 is shaped into a substantial rectangle. The overlapping area S is obtained by the product of a short side and a long side of the rectangle. When the movable comb 414 is displaced in the Z-axis direction, the long side of the overlapping area S does not change, and the short side becomes shorter in proportion to the displacement of the movable comb 414. As a result, the overlapping area S also decreases in proportion to the displacement of the movable comb 414. Since the movable comb 414 is displaced together with the first mirror 101, the overlapping area S decreases in proportion to the displacement of the first mirror 101.

As to a movable comb and a stationary comb, for example, the movable comb tilts with respect to the stationary comb. Here, an overlapping portion of the movable comb and the stationary comb is not always shaped into a rectangle. The shape of the overlapping portion changes depending on a tilted state of the movable comb. Accordingly, the overlapping area does not always change in proportion to the displacement of the movable comb. Furthermore, in the tilting, the displacement with respect to the tilt angle becomes greater as the tilted portion is farther distant from a center of the tilt. Hence, a tilted portion, of the movable comb, distant from the center of the tilt does not overlap the stationary comb when a displacement of a member to which the movable comb is connected becomes great. If the distance between the movable comb and the stationary comb is very short even though the movable comb does not overlap the stationary comb, a capacitance is created by the fringe effect; however, if the movable comb and the stationary comb are apart from each other at a certain distance, the distance keeps the capacitance from changing. Specifically, the configuration in which the movable comb tilts does not effectively utilize the overlapping area of the movable comb and the stationary comb for detecting the change of the capacitance.

Whereas, in the detection electrode 400, the overlapping area S changes in proportion to a displacement of the first mirror 101. Hence, the capacitance between the movable comb electrode 410 and the stationary comb electrode 420 also changes substantially in proportion to the displacement of the first mirror 101. Hence, throughout a range of motion of the first mirror 101, the capacitance uniformly changes as the first mirror 101 is displaced. As a result, no matter how much the first mirror 101 is displaced, the displacement of the first mirror 101 may be detected based on the capacitance with substantially the same precision as the capacitance is detected. Furthermore, the displacement of the movable combs 414 is substantially equal to that of the first mirror 101. Such a feature makes it possible to effectively utilize the areas of the movable combs 414 and the stationary combs 424 so as to detect the change in the capacitance.

As described above, the optical filter device 1000 includes: the first mirror 101; the actuators 300 driving the first mirror 101; and the detection electrode 400 detecting the displacement of the first mirror 101. The detection electrode 400 includes: the movable comb electrode 410 including movable combs 414 and connected to the first mirror 101; and the stationary comb electrode 420 including stationary combs 424 facing the movable combs 414 substantially in parallel with each other. The movable combs 414 are displaced in parallel with the stationary combs 424 when the movable comb electrode 410 is displaced together with the first mirror 101. Note that the state where the movable combs 414 are displaced in parallel with the stationary combs 424 is that the movable combs 414 and the stationary combs 424 may be arranged so that the change in the capacitance between the movable comb electrode 410 and the stationary comb electrode 420 is substantially proportional to the displacement of the movable combs 414.

Such features make it possible to detect the displacement of the first mirror 101 based on the change in the capacitance between the movable comb electrode 410 and the stationary comb electrode 420.

In detecting the change in capacitance between two electrodes, another possible option is to arrange two plate electrodes in parallel with each other, and detect the capacitance created due to the change in the space between the two plate electrodes. However, the capacitance between the plate electrodes is inversely proportional to the space, and the wider the space is, the less precise the detection of the capacitance is.

In contrast, the use of comb electrodes solves the problem of the plate electrodes. In the comb electrodes, the movable combs 414 of the movable comb electrode 410 and the stationary combs 424 of the stationary comb electrode 420 face each other without contact. In this state, the movable comb electrode 410 is displaced such that the overlapping areas S of the movable combs 414 and the stationary combs 424 change, followed by the change in the capacitance between the movable combs 414 and the stationary combs 424. The capacitance of the comb electrodes is proportional to the overlapping areas S. Such a feature makes it possible to precisely detect the change in the capacitance.

In addition, the movable combs 414, which are displaced together with the first mirror 101, are displaced in parallel with the stationary combs 424. Thus, the overlapping areas S of the movable combs 414 and the stationary combs 424 change substantially in proportion to the displacement of the first mirror 101. Such a feature makes it possible to detect the displacement of the first mirror 101 with uniform precision no matter how much the displacement is. As a result, precision may improve in detecting the displacement of the first mirror 101 throughout a displacement detectable area. Moreover, the relationship of a displacement of the first mirror 101 to a change in the capacitance is uniform throughout the displacement detectable area. Such a feature allows the displacement of the first mirror 101 to be more controllable.

Furthermore, the actuator 300 includes actuators 300. Each of the actuators 300 is connected to a different portion of the first mirror 101. The detection electrode 400 includes detection electrodes 400. The movable comb electrode 410 includes movable comb electrodes 410, and each of the movable comb electrodes 410 is connected to a different portion of the first mirror 101.

In these features, the first mirror 101 is driven by the actuators 300. Multiple actuators 300 are provided for multiple detection electrodes 400. Hence, each of the detection electrodes 400 is provided to a corresponding one of the actuators 300. Such a feature makes it possible to detect the displacement of the first mirror 101 caused by an actuator 300, using a detection electrode 400 corresponding to the actuator 300.

Moreover, the first mirror 101 is provided with the attachment 103 to which the actuator 300 is connected, and the movable comb electrode 410 is connected to the attachment 103.

In this feature, the movable comb electrode 410 is connected to a portion, of the first mirror 101, to which the actuator 300 is also connected. Specifically, the movable comb electrode 410 is displaced together with a portion, of the first mirror 101, to be directly moved by the actuator 300. Such a feature makes it possible to accurately detect, using the detection electrode 400, the displacement of the first mirror 101 caused by the actuator 300.

Furthermore, the first mirror 101 includes the mirror body 102. The attachment 103 extends from the mirror body 102. The actuator 300 is connected to the attachment 103 via the hinge 105 that is elastic and formed of a meandering line. The actuator 300 curves to drive the first mirror 101. The hinge 105 stretches when the actuator 300 curves. The movable comb electrode 410 is connected to a portion, of the attachment 103, across from a portion, of the attachment, to which the actuator 300 is attached.

In this feature, the actuator 300 curves when driving the first mirror 101. The portion, of the actuator 300, connected to the first mirror 101 is displaced in a direction (the Z-axis direction) to change the space between the first mirror 101 and the second mirror 201. In addition, the portion is also slightly displaced in another direction (the X-axis direction.) Since the actuator 300 is connected to the attachment 103 via the elastic hinge 105, the hinge 105 may absorb unnecessary displacement of the actuator 300. Since the hinge 105 is placed to stretch when the actuator 300 curves, meandering lines do not interfere with one another, contributing to absorbing unnecessary displacement of the actuator 300. Moreover, the attachment 103 extends from the mirror body 102 so that the actuator 300 and the hinge 105 may be arranged more flexibly. Consequently, the hinge 105 may be placed as described above. Then, the movable comb electrode 410 may be provided with the use of the attachment 103 disposed to flexibly arrange the actuator 300 and the hinge 105. As described above, this attachment 103 is a part, of the first mirror 101, to which the actuator 300 is attached. Such a feature makes it possible to accurately detect the displacement of the first mirror 101 caused by the actuator 300.

In addition, the actuator 300 includes two actuators 300, and the movable comb electrode 410 includes two movable comb electrodes 410. The attachment 103 includes two attachments 103 provided on the straight line L1 passing through the center C of the mirror body 102 and arranged to face each other across the center C. Each of the actuators 300 is connected to a corresponding one of the attachments 103 via the hinge 105 including hinges 105. The hinges 105 include at least two hinges 105 arranged to face each other across the straight line L1.

In this feature, the attachments 103 are provided on the straight line L1 passing through the center C of the mirror body 102, and arranged to face each other across the center C. Such a feature allows the actuators 300, as well as the movable comb electrodes 410, to be provided on the straight line L1 passing through the center C of the mirror body 102, and arranged to face each other across the center C. Specifically, the first mirror 101 has two portions to be displaced by the actuators 300. The two portions are (i) provided on the straight line L1 passing through the center C of the mirror body 102, and (ii) facing each other across the center C. In this feature, the first mirror 101 could rotate about the straight line L1. As a countermeasure, each actuator 300 is connected to an attachment 103 via the hinges 105. The at least two hinges 105 are arranged to face each other across the straight line L1. Hence, for each actuator 300, two hinges 105 may be arranged across the straight line L1 to prevent the first mirror 101 from rotating about the straight line L1. As a result, the first mirror 101 may be displaced while being kept in parallel with the second mirror 201 as much as possible.

In addition, the optical filter device 1000 further includes the second mirror 201 spaced apart from the first mirror 101. The actuators 300 drive the first mirror 101 to change the space between the first mirror 101 and the second mirror 201. The first mirror 101 and the second mirror 201 transmit portion of the incident light, and let portion of the incident light having a wavelength in accordance with the space exit.

Such features make it possible to precisely detect the displacement of the first mirror 101 to precisely adjust the space between the first mirror 101 and the second mirror 201. As a result, the features allow for precise control of the wavelength of the exiting light from the optical filter device 1000.

<<Other Embodiments>>

As can be seen, the above embodiment is described as an example of the technique disclosed in the present application. However, the technique recited in the present disclosure shall not be limited to the one in the above embodiment. Instead, the technique may have any given modification, replacement of a feature with another feature, additional feature, and omission of a feature to be applied to other embodiments. The constituent elements described in the above embodiment may be combined to create a new embodiment. The constituent elements in the attached drawings and the detailed description may include not only those essential to solve the problems, but also those which might not be essential to solve the problems in order to show the technique as an example. Thus, those inessential constituent elements shall not be determined as essential ones simply because such elements are found in the attached drawings and the detailed description.

The above embodiment of the present invention may be configured as follows.

The optical element shall not be limited to the optical filter device 1000. The detection by the above movable comb electrode and stationary comb electrode may be applied as long as the optical element causes an actuator to drive a mirror. Specifically, the detection technique is effective for an optical element causing the mirror to be displaced while maintaining the slope of the mirror as much as possible.

In the optical filter device 1000, the first mirror 101 is displaced to move away from the second mirror 201; however, the displacement shall not be limited to this. The first mirror 101 may be displaced to come closer to the second mirror 201. For example, the first unit 100 may be laid over the second unit 200.

Two actuators 300 are provided; however, three or more actuators 300 may be provided. Two detection electrodes 400 are provided; however, three or more detection electrodes 400 may be provided. Note that the detection electrode 400 may beneficially be equal in number to the actuators 300.

The movable comb electrode 410 may be secured to a portion, of the first mirror 101, on which the actuator 300 is not secured. Specifically, the movable comb electrode 410 may be provided in any given place as long as the feedback control can be performed on a drive voltage of the actuators 300 based on capacitance of the detection electrodes 400.

Each of the actuators 300 is connected to the first mirror 101 via two hinges 105; however, one hinge 105 or three or more hinges 105 may be connected. When three or more hinges 105 are connected, at least two of the hinges 105 are beneficially arranged across the straight line L1.

The actuator 300 is, but not limited to, a piezoelectric actuator which curves by a piezoelectric effect. For example, each actuator 300 may be a thermal actuator which comprises a beam including materials each having a different CTE. The thermal actuator curves due to a difference between the CTEs.

The actuator 300 includes two beams; namely, the first beam 301 and the second beam 302. However, the actuator 300 may include one beam or three or more beams.

The second beam 302 is provided with the dummy film 319; however, the dummy film 319 may be omitted.

The first mirror 101 includes the cylinder 104; however, the cylinder 104 may be omitted.

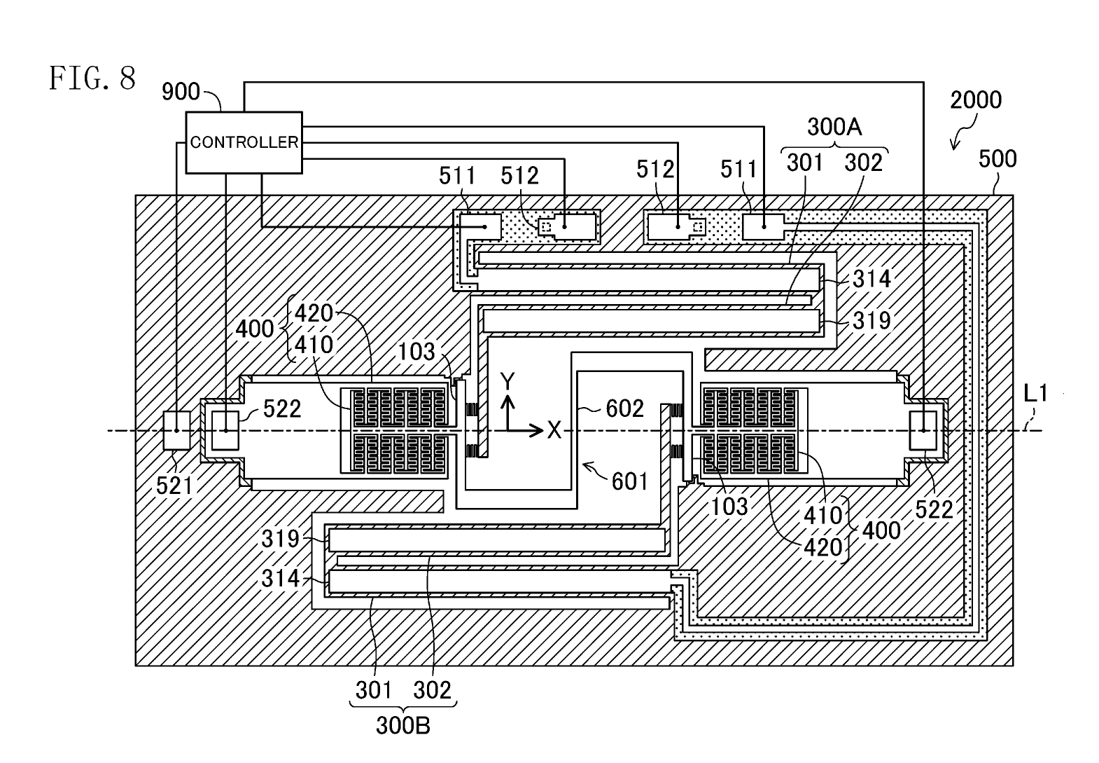

Alternatively, the first mirror 101 may be replaced with a blade, so that a shutter device including the blade may precisely detect displacement of the blade. FIG. 8 is a plan view of such a shutter device; namely a shutter device 2000. The mirror 101 in FIG. 2 is replaced with a blade 601. Other constituent elements are directly adopted from the optical filter device 1000 to constitute the shutter device 2000.

The blade 601 includes a blade body 602 and the two attachments 103. The blade body 602 is shaped into a plate-like substantial square. The mirror 101 is connected to the tip end of the second beam 302 so that a surface of the mirror 101 is in parallel with the surfaces of the first beam 301 and the second beam 302 (see FIG. 2); whereas, the blade 601 is connected to a tip end of the second beam 302 so that a surface of the blade 601 is vertical to surfaces of the first beam 301 and the second beam 302. Specifically, in FIG. 8, the thickness (a side surface) of the blade body 602 is illustrated. A surface of the blade body 602 is in parallel with a plane defined by the Y-axis and the Z-axis. Then, when the actuators 300 drive the blade 601, the blade 601 is displaced in the Z-axis direction. Such displacement may provide and close a not-shown light path in the X-axis direction.

In such a shutter device 2000, the displacement of the blade 601 may be detected based on change in capacitance between the movable comb electrode 410 and the stationary comb electrode 420.

Note that the surface of the blade body 602 does not have to be in parallel with the plane defined by the Y-axis and the Z-axis. The surface may be in parallel with a plane defined by, for example, the X-axis and Z-axis, depending on the not-shown light path to be blocked and provided by the blade 601.

### INDUSTRIAL APPLICABILITY

As can be seen, the technique disclosed here is useful for optical elements.

### DESCRIPTION OF REFERENCE CHARACTERS

1000 Optical Filter Device (Optical Element)

101 First Mirror (Moving Unit)

103 Attachment

105 Hinge (Connector)

201 Second Mirror (Another Moving Unit)

300A First Actuator

300B Second Actuator

400 Detection Electrode

410 Movable Comb Electrode

414 Movable Comb

420 Stationary Comb Electrode

424 Stationary Comb

601 Blade (Moving Unit)

2000 Shutter Device (Optical Element)

1. An optical element comprising:
a moving unit;
an actuator driving the moving unit; and
a detection electrode detecting displacement of the moving unit,
the detection electrode including:
a movable comb electrode including movable combs and connected to the moving unit; and
a stationary comb electrode including stationary combs facing the movable combs in parallel with each other, and
the movable combs being displaced in parallel with the stationary combs and along a thickness of the movable combs when the movable comb electrode is displaced together with the moving unit.

2. The optical element of claim 1, wherein
the actuator includes actuators,
each of the actuators is connected to a different portion of the moving unit,
the detection electrode includes detection electrodes, and
the movable comb electrode includes movable comb electrodes, and each of the movable comb electrodes is connected to a different portion of the moving unit.

3. The optical element of claim 2, wherein
the moving unit is provided with an attachment to which the actuator is connected, and
the movable comb electrode is connected to the attachment.

4. The optical element of claim 3, wherein
the moving unit is a mirror including a mirror body,
the attachment extends from the mirror body,
the actuator is connected to the attachment via a connector which is elastic and formed of a meandering line,
the actuator curves to drive the moving unit,
the connector stretches when the actuator curves, and
the movable comb electrode is connected to a portion, of the attachment, across from a portion, of the attachment, to which the actuator is attached.

5. The optical element of claim 4, wherein
the actuator includes two actuators and the movable comb electrode includes two movable comb electrodes,
the attachment includes two attachments provided on a straight line passing through a center of the mirror body and arranged to face each other across the center,
each of the actuators is connected to a corresponding one of the two attachments via the connector including connectors, and
the connectors include at least two connectors arranged to face each other across the straight line.

6. The optical element of claim 1, further comprising
an other moving unit spaced apart from the moving unit, wherein
the moving unit is a mirror and the other moving unit is a mirror,
the actuator drives the moving unit to change a space between the moving unit and the other moving unit, and
the moving unit and the other moving unit transmit portion of incident light, and let portion of the incident light having a wavelength in accordance with the space exit.
